(19) United States
(12) Patent Application Publication
(10) Pub. No.: US 2003/0020455 A1
(43) Pub. Date: Jan. 30, 2003

(54) Method and apparatus for measuring electrical energy consumption for multiple consumers

(76) Inventor: Richard L. Longini, Cranberry Township, PA (US)

Correspondence Address: CAROTHERS AND CAROTHERS, Suite 500, 445 Fort Pitt Blvd., Pittsburgh, PA, 15219, US

(21) Appl. No.: 09/917,333

(22) Filed: Jul. 30, 2001

(51) Int. Cl. G01R 7/00

(52) U.S. Cl. 324/142

(57) ABSTRACT

An electrical energy consumption meter for measuring electrical energy consumption from multiple consumer individual transmission lines that are connected to one power supply system having a plurality of transmission line conductors carrying alternating current. The meter includes a voltage pickup connected to one transmission line for measuring voltage between conductors. Multiple current factor pickups are respectively connected to each individual customer transmission line for measuring a factor of the electrical current flowing in each individual customer transmission line. A computer within the meter is connected to all of the pickups for computing the power being consumed by each of the multiple customers through each individual customer transmission thereby providing multiple power consumption readings with a single meter.

### FIELD OF THE INVENTION

The invention relates generally to metering electrical energy consumption and more particularly to measuring electrical energy consumption for multiple consumers.

### BACKGROUND OF THE INVENTION

The present invention pertains to the measurement of energy consumption by a load connected to an electrical transmission line that in turn is connected to an alternating current source or supply. Typical examples might be the supply of alternating current to a home or residence in the form of single phase alternating current, or to a commercial or industrial user in the form of a three-phase alternating current supply.

The term meter is herein used to describe apparatus for sensing and processing information used for determining energy distribution to customers from an electric power distribution utility. Present day meters are either of an analog type or a digital type and one meter is provided for each consumer. Examples of existing digital meter technology is shown in the inventor's U.S. Pat. Nos. 5,061,890 and 5,517,106.

Such prior art metering systems are disadvantageous because a meter must be provided for each consumer and each meter must be positioned directly adjacent the consumer facility, making such metering systems expensive and making meter reading an arduous task.

It is a principal object of the present invention to provide a method and apparatus whereby only one meter need be provided for multiple consumers and to further provide the option whereby the meter may be physically positioned next to the power transformer supplying multiple consumers, as opposed to being attached to the consumer's building or facilities.

### SUMMARY OF THE INVENTION

The present invention provides a method and apparatus for measuring electrical energy consumption for multiple consumers served from individual customer transmission lines connected to one power supply system having a plurality of transmission line conductors carrying alternating current. A single voltage pickup is connected to the transmission line for measuring voltage between conductors and multiple current pickups are respectively connected to each individual customer transmission line for measuring a factor of the electrical current flowing in each individual customer transmission line.

Here the term “factor of the electrical current flowing” is used to indicate the alternative possibility of either measuring the actual current or the current derivative with the pickup, which are possible alternatives for measurement as is explained in the aforementioned U.S. Pat. Nos. 5,061,890 and 5,517,106.

A computer in the meter is connected to all of the pickups for computing the power being consumed by each of the individual customers through each individual customer transmission line.

The arrangement of the present invention permits the customer's voltages to be sensed at the transformer and therefore voltages are only determined jointly for all users rather than being read at each individual user facility. Another advantage is that the system of the present invention is easier to install and service and a remote reading or control system need only to interact with the single meter instead of the multiple individual meters for each meter of the prior art for each customer.

The meter of the present invention also preferably includes a meter timer synchronized with measured voltage for synchronizing computations of power. In addition, the current factor pickups may include an amplifier for amplifying the measurements and they may further include a storage medium for storing a calibration number associated with each pickup for providing calibrated computations by the computer contained in the meter. Accordingly, the meter will have individual calibration factors for each pickup or sensor and these calibration factors need only to be activated when sensed or computed values are being transmitted to remote places or being sent to more local display systems.

### BRIEF DESCRIPTION OF THE DRAWINGS

Other objects and advantages appear hereinafter in the following description and claims. The appended drawings show, for the purpose of exemplification, without limiting the invention or appended claims, certain practical embodiments of the present invention wherein:

FIG. 1 is a schematic diagram of a meter illustrating the method and apparatus of the present invention; and

FIG. 2 is a schematic diagram illustrating the details of a current factor pickup for the meter shown in FIG. 1.

### DESCRIPTION OF A PREFERRED EMBODIMENT

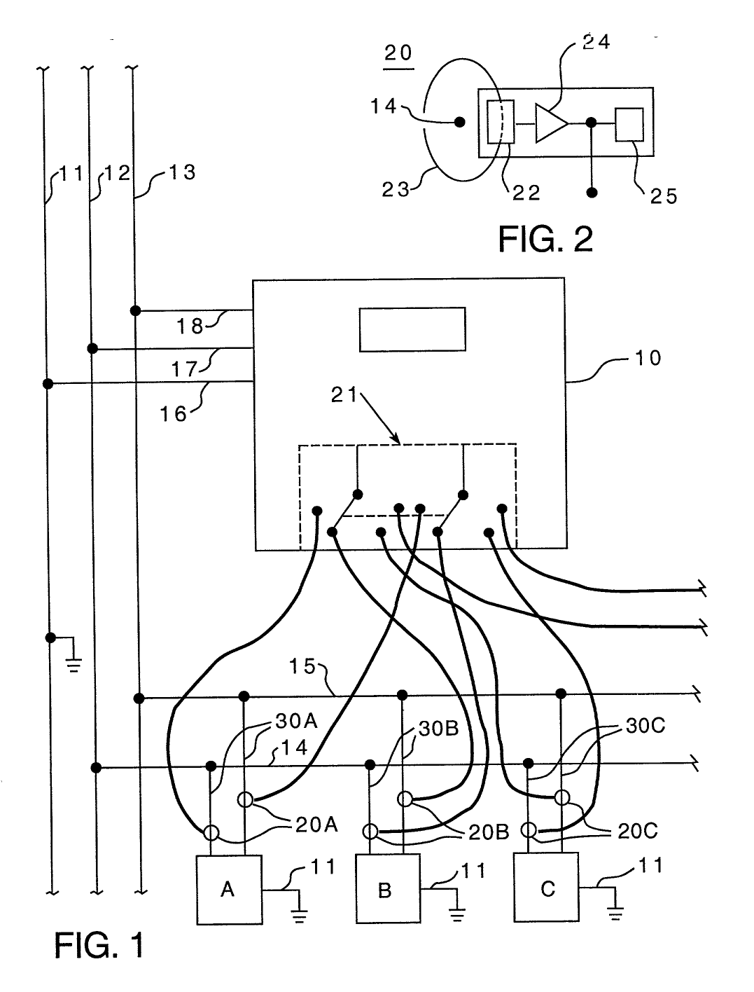

Referring to FIG. 1, the meter 10 of the present invention incorporates for the most part known meter technology such as the digital meter shown and illustrated in U.S. Pat. No. 5,061,890, and accordingly, the body of that patent is incorporated herein by reference to explain the inner workings of the meter 10, with the exception of those parts to be hereinafter explained and described in detail.

Transmission line conductors 11, 12 and 13 carry an alternating current supplied from an alternating current source (not shown) through a transformer (not shown) in a conventional fashion. This system will be described with a three wire single phase source. However, it must be understood that the method and apparatus of the present invention will work equally well with a two wire, single phase or any multiple phase current source.

A two wire single phase transmission branch consisting of transmission lines 14 and 15 are split off from the main transmission lines 11, 12 and 13 as indicated to supply multiple customers as indicated at loads A, B and C. Lines 14 and 15 continue on to supply other consumers.

Meter 10 is provided with voltage pickups from the main transmission line conductors 11 12 and 13 in the form of voltage tap lines 16, 17 and 18, which provide voltage pickups in combination with a conventional resistor bridge (not shown) as is fully described in the aforementioned U.S. Pat. No. 5,061,890.

Current factor pickups 20A, 20B and 20C are respectively connected to each individual transmission line pair 30A, 30B and 30C for measuring a factor of the electrical current flowing in each individual customer transmission line. Here the pickups 20A, 20B and 20C are provided in the form of Rogowski coils, as is filly described in the aforementioned patent, to measure the timed derivative of the magnetic field induced by current flowing in the respective conductor pairs. Of course, as an alternative, the current factor pickups may be provided instead in the form of current pickups as is described in U.S. Pat. No. 5,517,106.

The meter 10 contains a computer, as is described in the aforementioned patents, which is connected to all of the pickups for computing the power being consumed by each of the multiple customers through each individual customer transmission line, the computation being carried out as explained in the aforementioned patents.

In order to sequentially measure the respective currents or current derivatives of the individual customer lines 30A, 30B or 30C, the meter is provided with a current signal multiplexer ganged switching system as indicated at 21. It is schematically illustrated as a mechanical switching system, but is in reality an electronic switch.

The result is that the voltage measurement for the meter is made at only one location for all customers from the main transmission line conductors 11, 12 and 13 and the current readings may be taken adjacent the power transmission line conductors 14 and 15 instead of at a more remote location on the individual customer facilities or buildings. Most importantly, only one meter is required to read or meter the consumption of multiple consumer loads and this meter is provided at a convenient location for reading.

Turning next to FIG. 2, an enlarged view is schematically illustrated of the current pickups 20A, 20B and 20C, and is here merely indicated as 20. This pickup in its basic form is the same as that described in U.S. Pat. No. 5,061,890. This pickup includes a coil of hundreds of turns which is used as a derivative current pickup coil 22. Each current derivative pickup consists of a pickup wire coil wound or coiled about a non-ferrous core 23 as indicated at 22 which passes around the conductor 14. The current factor pickups 20 further include an amplifier 24 for amplifying the measurement. In addition, they further include a storage medium 25 for storing a correction factor number associated with each pickup for providing calibrated computations by the computer for correction to a calibration factor built into meter 10. This is a small, such as a two byte or more storage space, to store a calibration number to be read by the meter. This number might for example be a factor for the meter to use to make the reading more precise.

I claim:

1. The method of measuring electrical energy consumption for multiple consumers served from individual customer transmission lines connected to one power supply system having a plurality of transmission line conductors carrying alternating current, the method comprising:
measuring the voltage between conductors of the one transmission line;
measuring a factor of the electrical current flowing in each individual customer transmission line; and
computing the energy being consumed by each of the multiple customers through each individual customer transmission line using said voltage measurement and said individual customer current factor measurements.

2. The method of claim 1 wherein measuring a factor of the electrical current includes taking a measurement selected from the group of measurements consisting of measuring actual current and measuring current derivative.

3. The method of claim 2 wherein computing includes synchronizing computations of energy consumption with a meter timer synchronized with the voltage measurement.

4. The method of claim 2 wherein measuring the current factor includes amplifying the measurement thereof.

5. The method of claim 2 including storing a calibration number associated with each current factor measurement and computing includes using said calibration number for providing a calibrated computation.

6. An electrical energy consumption meter for measuring electrical energy consumption from multiple consumer individual transmission lines connected to one power supply system having a plurality of transmission line conductors carrying alternating current, the meter comprising:
a voltage pickup connected to the one transmission line for measuring voltage between conductors;
current factor pickups respectively connected to each individual customer transmission line for measuring a factor of the electrical current flowing in each individual customer transmission line; and
computer means connected to all of said pickups for computing the energy being consumed by each of the multiple customers through each individual customer transmission.

7. The meter of claim 6 wherein the current factor pickups include means for taking a measurement selected from the group of measurements consisting of measuring current and measuring current derivative.

8. The meter of claim 6 wherein said computer means includes a meter timer synchronized with measured voltage for synchronizing computations of power.

9. The meter of claim 6 wherein each of said current factor pickups includes an amplifier for amplifying the measurement.

10. The meter of claim 6 wherein each of said current factor pickups includes a storage medium for storing a calibration number associated with each pickup for providing calibrated computations by said computer means.
